(19) United States
(12) Patent Application Publication
(10) Pub. No.: US 2025/0261563 A1
(43) Pub. Date: Aug. 14, 2025

(54) MAGNETOSTRICTIVE MATERIAL, ENERGY CONVERTER AND METHOD FOR MANUFACTURING THE SAME, AND VIBRATION POWER GENERATOR

(71) Applicants: TOHOKU UNIVERSITY, Sendai-shi, Miyagi (JP); TOHOKU STEEL CO., LTD., Sendai-shi, Miyagi (JP)

(72) Inventors: Hiroki KURITA, Sendai-shi (JP); Fumio NARITA, Sendai-shi (JP); Masahito WATANABE, Sendai-shi (JP); Kiyoshi URAKAWA, Sendai-shi (JP); Takenobu SATO, Sendai-shi (JP); Tatsuro SASA, Sendai-shi (JP); Daiki CHIBA, Sendai-shi (JP); Masumi HIROTANI, Sendai-shi (JP); Naoyuki OWARI, Sendai-shi (JP); Tsuyoki TAYAMA, Sendai-shi (JP); Takashi EBATA, Sendai-shi (JP)

(73) Assignees: TOHOKU UNIVERSITY, Sendai-shi, Miyagi (JP); TOHOKU STEEL CO., LTD., Sendai-shi, Miyagi (JP)

(21) Appl. No.: 18/848,419

(22) PCT Filed: Mar. 15, 2023
(86) PCT No.: PCT/JP2023/009997

§ 371 Date: May 6, 2025

(30) Foreign Application Priority Data
Mar. 18, 2022 (JP) 2022-044485

(51) Int. Cl. H10N 35/85; H10N 35/00; H10N 35/01

(52) U.S. Cl. CPC H10N 35/85; H10N 35/01; H10N 35/101

(57) ABSTRACT

[Problem] To provide a magnetostrictive material, an energy converter and a method for manufacturing the energy converter, and a vibration power generator, having improved energy efficiency and capable of reducing manufacturing costs.

[Solution] A magnetostrictive material includes a void. A plate-shaped magnetostrictive material includes a through hole in a plate thickness direction. An energy converter is formed by stacking and coupling a plate-shaped magnetostrictive material including a through hole in a plate thickness direction and a plate material in plate thickness direction to each other. The plate-shaped magnetostrictive material is formed of a honeycomb structure including a cell constituting the through hole. A cross sectional shape of the cell in the honeycomb structure is polygonal. The plate material is made of a magnetostrictive material, a soft magnetic material, or a nonmagnetic material. The plate-shaped magnetostrictive material and/or the plate material may be formed of a plurality of pieces, each of which is stacked and coupled in the plate thickness direction.

### FIELD OF THE INVENTION

The present invention relates to a magnetostrictive material, an energy converter and a method for manufacturing the same, and a vibration power generator.

### DESCRIPTION OF RELATED ART

Conventionally, an energy converter has been known formed by bonding a solid soft magnetic material and a solid magnetostrictive material (e.g., refer to Patent Literature 1).

### CITATION LIST

### Patent Literatures

Patent Literature 1: JP 6653834

### SUMMARY OF THE INVENTION

### Technical Problem

The energy converter described in Patent Literature 1 can be used for a vibration power generator, a force sensor device, an actuator, and the like, but there is a need for improved energy efficiency and lower manufacturing costs.

The present invention has been made focusing on those problems. The object of the present invention is to provide a magnetostrictive material, an energy converter and a method for manufacturing the energy converter, and a vibration power generator, having improved energy efficiency and capable of reducing manufacturing costs.

### Solution to Problem

To achieve the above-described object, a magnetostrictive material according to the present invention includes a void.

Since the magnetostrictive material according to the present invention includes the void, it is possible to increase an amount of deformation by a vibration and to improve energy efficiency.

The void may be formed partially or entirely.

A plate-shaped magnetostrictive material according to the present invention includes a through hole in a board plate thickness direction.

Since the magnetostrictive material according to the present invention includes the through hole in the board plate thickness direction, it is possible to increase an amount of deformation by a vibration and to improve energy efficiency.

An energy converter according to the present invention is formed by stacking and coupling a plate-shaped magnetostrictive material including a through hole in a plate thickness direction and a plate material in plate thickness direction to each other.

Since the energy converter according to the present invention includes the plate-shaped magnetostrictive material including the through hole in the plate thickness direction, it is possible to increase an amount of deformation by a vibration and to improve energy efficiency. Moreover, since it is formed by stacking and coupling the plate-shaped magnetostrictive material and the plate material in the plate thickness direction, a strength thereof can be increased.

The plate-shaped magnetostrictive material is preferably formed of a honeycomb structure including a cell constituting the through hole.

In this case, the honeycomb structure can increase a compressive strength in the plate thickness direction.

It is preferable that a cross sectional shape of the cell in the honeycomb structure is polygonal.

The plate material is preferably made of a magnetostrictive material, a soft magnetic material, or a nonmagnetic material.

When the plate material is made of the soft magnetic material, a change in magnetization due to an inverse magnetostriction effect of the magnetostrictive material can also change magnetization of the soft magnetic material, and energy efficiency due to the inverse magnetostriction effect can be improved compared with a case due to only the inverse magnetostriction effect of the magnetostrictive material.

The plate-shaped magnetostrictive material and/or the plate material may be formed of a plurality of pieces, each of which may be stacked and coupled in the plate thickness direction.

In this case, various-shaped plate-shaped magnetostrictive materials and/or plate materials can be stacked in the plate thickness direction to manufacture various-shaped energy converters.

The through hole of the plate-shaped magnetostrictive material may be closed at one or both ends by the plate material or another plate-shaped magnetostrictive material.

In this case, an outer appearance thereof is dense and lightweight while maintaining strength, and it is possible to increase an amount of deformation by a vibration and to improve energy efficiency.

The plate-shaped magnetostrictive material may be formed of a plurality of pieces, each of which may have a different direction of an easy axis of magnetization.

In this case, an internal stress can be improved.

The plate-shaped magnetostrictive material and the plate material may be bonded to each other by diffusion bonding, welding, or an adhesive.

The energy converter according to the present invention may be manufactured by a method of laminating and bonding one of a magnetostrictive layer formed by laminating and molding a raw material powder for the magnetostrictive material melted by a directed energy deposition method and a soft magnetic material layer formed by laminating and molding a raw material powder for the soft magnetic material melted by the directed energy deposition method to the other, but productive efficiency can be improved by bonding the plate-shaped magnetostrictive material to the plate material by the diffusion bonding, the welding, or the adhesive.

The energy converter according to the present invention may be in an elongated plate shape having a plate thickness that decreases from one end toward the other end.

The energy converter according to the present invention may be in an elongated plate shape having a width that narrows from one end toward the other end.

The energy converter according to the present invention may be in an elongated plate shape having a plate thickness that decreases and a width that narrows, from one end toward the other end.

A manufacturing method of an energy converter according to the present invention includes stacking and coupling a plate-shaped magnetostrictive material including a through hole in a plate thickness direction and a plate material in the plate thickness direction to each other.

In accordance with the manufacturing method of the energy converter according to the present invention, the above-mentioned energy converter can be manufactured at reduced manufacturing costs.

A vibration power generator according to the present invention includes a vibration unit formed by supporting the one end of this energy converter in a cantilever manner and is configured to generate electricity by an inverse magnetostriction effect of the plate-shaped magnetostrictive material due to vibration of the vibration unit.

The energy converter according to the present invention is in an elongated plate shape with a reduced thickness and/or narrower width from one end to the other, and thereby a stress is distributed and applied over the entirety. Thus, generation efficiency can be improved when the vibration unit is formed by supporting the one end in a cantilever manner to generate electricity by the inverse magnetostriction effect of the plate-shaped magnetostrictive material due to vibration of the vibration unit.

The vibration power generator according to the present invention may include the above-mentioned energy converter, the energy converter being elongated plate shape, one end thereof being supported, and may be configured to generate electricity by an inverse magnetostriction effect of the plate-shaped magnetostrictive material due to an impact in an overall longitudinal direction of the energy converter.

The energy converter according to the present invention may be in an elongated plate shape, the cross sectional shape of the cell in the honeycomb structure may be a regular hexagon, and a perpendicular line of any side of the cell may be inclined at 30 degrees with respect to the overall longitudinal direction.

In this case, when the vibration unit is formed by supporting the one end in a cantilever manner to generate electricity by the inverse magnetostriction effect of the plate-shaped magnetostrictive material due to vibration of the vibration unit, it is possible to increase an amount of deformation by the vibration and to increase an electric-generating capacity. Moreover, it is possible to reduce a resonant frequency.

The energy converter according to the present invention may be in an elongated plate shape, the cross sectional shape of the cell in the honeycomb structure may be a hexagon, the hexagon may have two opposing sides that are equal in length, the other four sides are each the same length but longer than the two opposing sides, and perpendicular lines with respect to the two sides may be along the overall longitudinal direction.

In this case, a portion where the inverse magnetostriction effect appears can be increased and energy efficiency can be improved.

In the energy converter according to the present invention, the plate-shaped magnetostrictive material may be formed of a plurality of pieces, which may be stacked and coupled in the plate thickness direction to each other, with the through holes shifted from each other.

The plate-shaped magnetostrictive material and the magnetostrictive material are preferably made of an Fe—Co based alloy, an Fe—Al based alloy, Ni, an Ni—Fe based alloy, or an Ni—Co based alloy.

The soft magnetic material is made of a material having a magnetostriction constant with an opposite sign to a magnetostrictive constant of the plate-shaped magnetostrictive material.

The nonmagnetic material is preferably stainless steel such as stainless-steel (SUS) 304 or SUS316, Ti, or the like. An overall strength can be increased by using the plate material made of such a high-strength nonmagnetic material.

The through holes in the plate-shaped magnetostrictive material may be formed in a part of the plate-shaped magnetostrictive material, or may be formed in the entirety thereof. The number of the through holes may be one or more.

The plate-shaped magnetostrictive material according to the present invention and the energy converter can be used in force sensors, actuators, and the like, in addition to the vibration power generator.

### Advantageous Effects of Invention

In accordance with the present invention, it is possible to provide a magnetostrictive material, an energy converter and a method for manufacturing the energy converter, and a vibration power generator, having improved energy efficiency and capable of reducing manufacturing costs.

### BRIEF DESCRIPTION OF THE DRAWINGS

FIG. 1 is a perspective diagram illustrating a configuration of an energy converter according to an embodiment of the present invention.

FIG. 2 is a perspective diagram illustrating a honeycomb structure in which cells used for a plate-shaped magnetostrictive material have a regular hexagonal cross-sectional shape.

FIG. 3 is a perspective diagram illustrating a honeycomb structure in which cells used for a plate-shaped magnetostrictive material have a square cross-sectional shape.

FIG. 4 is an explanatory diagram illustrating a structure in which a magnetic anisotropy of the energy converter according to the embodiment of the present invention is adjusted.

FIG. 5 is an explanatory diagram illustrating an example of a honeycomb structure.

FIG. 6 is an explanatory diagram illustrating a fabrication process of an energy converter in Example 1.

FIG. 7 is an explanatory diagram illustrating a honeycomb structure in Example 1.

FIG. 8(a) is a schematic diagram illustrates Fe52-Co48 alloy cubes manufactured using various parameters in Example 2 of the present invention, and FIG. 8(b) is a schematic diagram illustrating a scanning method used.

FIG. 9(a) is a schematic diagram illustrating a vibration-energy-harvesting performance test, and FIG. 9(b) is a schematic diagram illustrating an impact-energy-harvesting performance test.

FIG. 10 illustrates XRD patterns of the Fe52-Co48 alloy cubes obtained using each manufacturing parameter.

FIG. 11 illustrates a secondary electron image and EDX maps of the Fe52-Co48 alloy cube manufactured using a P2V1 parameter shown in Table 1.

FIG. 12 is a graphic chart illustrating a relationship between a porosity and an energy density of the Fe52-Co48 alloy cube manufactured with each parameter.

FIG. 13 is an appearance photograph of an Fe52-Co48 alloy plates having (a) a fully dense structure and (b) a honeycomb structure, manufactured using the P2V1.

FIG. 14(a) is a graphic chart illustrating a relationship of an output voltage with respect to a frequency of the Fe52-Co48 alloy plates having a fully dense structure and a honeycomb structure in the vibration-energy-harvesting test, and FIG. 14(b) is a graphic chart illustrating a relationship of a power density with respect to a resistance at a resonant frequency of each alloy plate.

FIG. 15 is a graphic chart illustrating power densities of the Fe52-Co48 alloy plates having a fully dense structure and a honeycomb structure in the impact-energy-harvesting test.

FIG. 16 is a front view diagram illustrating shapes of samples for an impact-power-generation test in Example 3.

FIG. 17 is a schematic diagram illustrating an impact-energy-harvesting performance test apparatus in Example 3.

FIG. 18 is a graphic chart illustrates instantaneous current values (with correction of volume) with respect to heights of free fall of a weight in the impact-power-generation test in Example 3.

### DETAILED DESCRIPTION OF THE INVENTION

Hereinafter, embodiments of the present invention will be described.

As illustrated in FIG. 1, an energy converter according to the embodiment of the present invention is formed by stacking and coupling a plate-shaped magnetostrictive material including a through hole(s) in a plate thickness direction and a plate material in the plate thickness direction to each other.

The plate material is made of a magnetostrictive material, a soft magnetic material, or a nonmagnetic material. The plate-shaped magnetostrictive material and the magnetostrictive material are made of an Fe—Co based alloy, an Fe—Al based alloy, Ni, an Ni—Fe based alloy, or an Ni—Co based alloy. The soft magnetic material is made of a material having a magnetostriction constant with an opposite sign to a magnetostrictive constant of the plate-shaped magnetostrictive material. The nonmagnetic material is made of stainless steel such as SUS304 or SUS316, Ti, or the like.

The plate-shaped magnetostrictive material and the plate material are shaped by etching processing, laser processing, press processing, electrolytic processing (wire cutting, electric discharging), or the like on a thin plate of a magnetostrictive material, a soft magnetic material, or a nonmagnetic material. The through hole is formed in the plate-shaped magnetostrictive material. The plate-shaped magnetostrictive material includes the through hole formed in the board plate thickness direction, and thereby it is possible to increase an amount of deformation by a vibration and to improve energy efficiency.

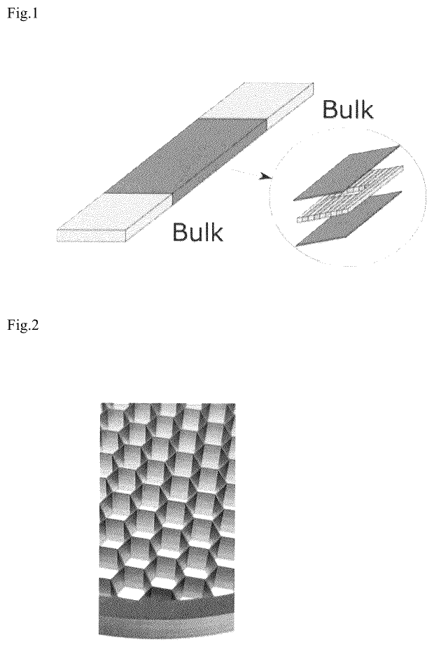

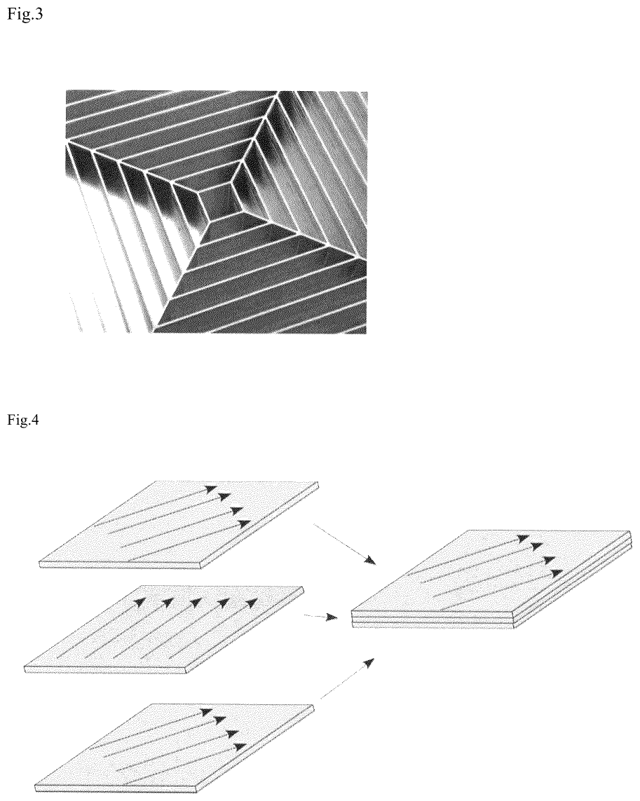

The plate-shaped magnetostrictive material and the plate material are processed, for example, to be a honeycomb structure so that each cell form a through hole, when laminated. In the honeycomb structure, the cross-sectional shape of the cells may be any polygonal shape such as a square (refer to FIG. 3) other than a regular hexagon (refer to FIG. 2). The honeycomb structure can increase an output power density per unit volume of the magnetostrictive material.

The fabricated plate-shaped magnetostrictive material and plate material are laminated in the plate thickness direction, fixed with a jig, and then placed in an electric furnace, and heated and pressurized to be diffusion-bonded. The conditions for the diffusion bonding are preferably a recrystallization temperature of 600 to 1000° C. or higher, a load of 0.1 to 100 kg/cm², and a holding time of 0.5 to 30 hours.

The plate-shaped magnetostrictive material and the plate material may be bonded by welding or an adhesive, as well as the diffusion bonding. In the case of bonding by an adhesive, it is preferable to apply the adhesive to the plate-shaped magnetostrictive material or plate material, and then the plate-shaped magnetostrictive material and plate material are fixed with a jig and adhered by heating and pressurizing. Productive efficiency can be improved by bonding the plate-shaped magnetostrictive material to the plate material by the diffusion bonding, the welding, or the adhesive.

The number of laminated layers may be a single layer or any number of multiple layers. For example, it may be 800 or more laminated layers. By laminating the plate-shaped magnetostrictive material and the plate material so that one end or both ends of the through hole in the plate-shaped magnetostrictive material is closed by the plate material or another plate-shaped magnetostrictive material, one side or both sides thereof can be formed as a hollow structure with a dense structure or bulk structure.

The dense structure or bulk structure of both sides are made of a nonmagnetic material, such as stainless steel such as SUS304 or SUS316, or Ti, and the internal hollow structure is made of a pair of a magnetostrictive material and an inverse-magnetostrictive material, thereby increasing strength.

Moreover, since the energy converter includes the plate-shaped magnetostrictive material including the through hole in the plate thickness direction, it is possible to increase an amount of deformation by a vibration and to improve energy efficiency.

As illustrated in FIG. 4, a plurality of plate-shaped magnetostrictive materials may have a structure of the magnetic anisotropy laminated is adjusted so that directions of the easy axis of magnetization are different from one another.

After bonding the plate-shaped magnetostrictive material and the plate material to each other, the energy converter is individualized by cutting them by shear cutting, wire cutting, laser cutting or the like. Energy converters having different properties can be manufactured depending on the cutting direction of the plate-shaped magnetostrictive material and the plate material.

The magnetostrictive material according to the embodiment of the present invention has a structure of having a void(s). The structure of having the void(s) may be any structure which is not dense. The magnetostrictive material having the void(s) may be formed of a mesh-like hollow tube structure, for example, as carbon nanotubes.

Preferred structures for the voids of the magnetostrictive material include a structure of having voids over three dimensions, a structure of having voids partially or entirely, a structure where a stress is distributed over the entire longitudinal direction, a structure where density varies in longitudinal direction, and the like.

The magnetostrictive material according to the embodiment of the present invention includes a void(s), and is therefore flexible, and can efficiently convert minute mechanical energy, such as vibrations caused by an environment, into mechanical energy for a device. An amount of strain of the magnetostrictive material for converting mechanical energy into electrical energy can be increased. Greater power generation can be obtained by designing the void structure to be more stress concentrated.

The energy converter can be formed, for example, in an elongated plate shape having a honeycomb structure. In this case, the cross sectional shape of the cell may be in a regular hexagon and a perpendicular line of any sides of the cell may be inclined at 30 degrees with respect to the overall longitudinal direction. Moreover, as illustrated in FIG. 5, the cross sectional shape of the cell may be in a regular hexagon, the hexagon may have two opposing sides that are equal in length, the other four sides that are each the same length but longer than the two opposing sides, and perpendicular lines with respect to the two sides may be along the overall longitudinal direction.

Moreover, the energy converter may be in an elongated plate shape having a plate thickness that decreases from one end toward the other end. The energy converter may be in an elongated plate shape having a width that narrows from one end toward the other end. The energy converter may have a plate thickness that decreases and a width that narrows, from one end toward the other end.

The vibration power generator includes a vibration unit formed by supporting the one end of this energy converter in a cantilever manner and is configured to generate electricity by the inverse magnetostriction effect of the plate-shaped magnetostrictive material due to vibration of the vibration unit. For example, a pickup can be provided at a periphery of the energy converter and an induced current can be generated in the pickup by the inverse magnetostriction effect of the magnetostrictive material due to vibration (refer to FIGS. 9(a) and 9(b)). The pickup can be formed of a coil inside which the energy converter is disposed.

The energy converter is in an elongated plate shape with a reduced thickness and/or narrower width from one end to the other, and thereby a stress is distributed and applied over the entirety, and thereby generation efficiency can be improved.

The entire energy converter contributes to power generation by applying stress to the entire structure, thereby increasing energy efficiency or power generation efficiency.

It is to be noted that, when an installation space near a vibration unit is limited, the energy converter may be designed to have an outside shape, a stress, and distribution of a stress concentration portion that efficiently obtain power output, in accordance with a shape of the installing space and vibration conditions.

### Example 1

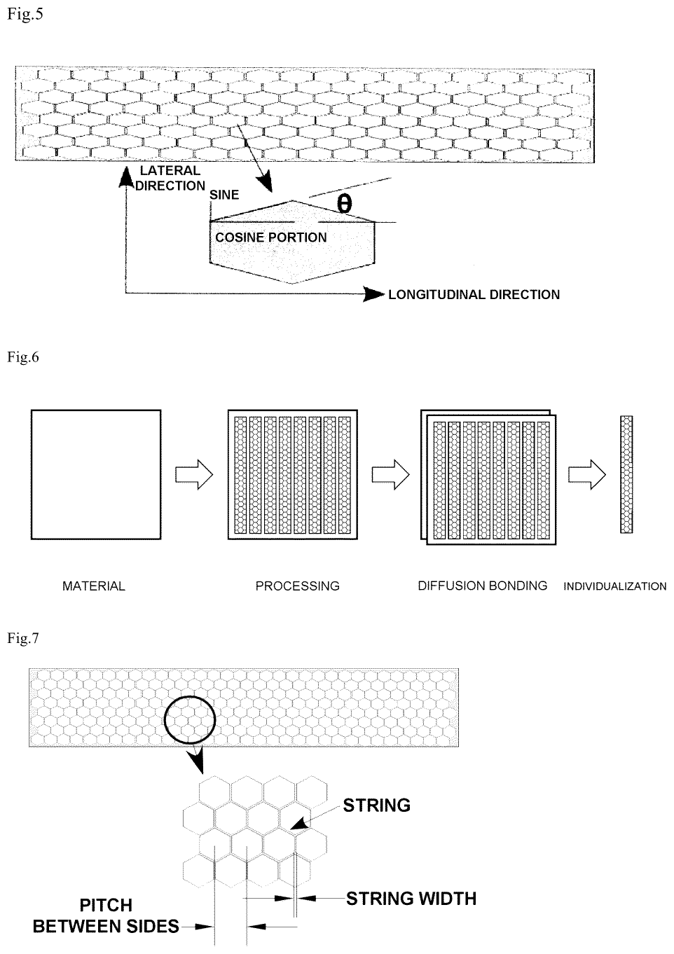

An energy converter is fabricated in accordance with a process illustrated in FIG. 7. First, an alloy based on Fe and 70% by mass of Co having a positive magnetostriction constant is melted, forged, and rolled to fabricate a plate-shaped magnetostrictive material having dimensions of 100 mm×100 mm×0.1 mm. Furthermore, an Ni plate material of similar size is prepared. The plate-shaped magnetostrictive material and the plate material are processed into a honeycomb structure using wet etching. A string width is 0.1 mm and a pitch between sides is 1 mm (refer to FIG. 6). The plate-shaped magnetostrictive material and the plate material are designed to have a cutting margin of 0.5 mm wide so as to be individualized to eight pieces. The plate-shaped magnetostrictive material and the plate material of honeycomb structure are stacked and loaded into a fixing jig, and are fixed with an outer frame. The fixed plate-shaped magnetostrictive material and plate material are loaded into an electric furnace and heated and held at about 750° C. for 10 hours, and then are cooled. The plate-shaped magnetostrictive material and the plate material which are diffusion-bonded to each other are extracted from the electric furnace, bent and cut to be individualized in 90 mm in length, 8.5 mm in width, and 0.2 mm in thickness. Thus, the energy converter is fabricated.

### Example 2

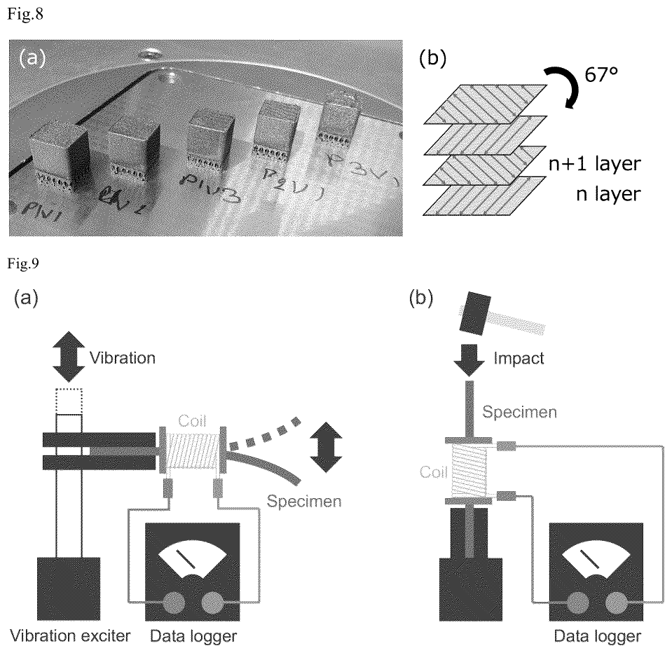

Fe52-Co48 alloy cubes (10×10×9 mm³, refer to FIG. 8(a)) are manufactured by a laser-powder-bed fusion (LPBF) process (SLM280HL, SLM Solutions Group AG) under an argon atmosphere. Fe52-Co48 alloy powder (TIZ Advanced Alloy Technology Co., Ltd.) with a D50 particle diameter of 39 μm is used. All specimens are built on an S355 steel platform.

It has been known that the magnetostriction for a whole spray-cast Fe(100−x)-Cox binary series, the magnetostriction increases with an increase in Co content and reaches approximately 110 ppm for Co compositions between 40 at. % and 60 at. %. Fe52-Co48 is one of reasonable ratios, and Fe—Co alloy powder with this ratio has been commercially fabricated. The processing of new materials with metallic additive manufacturing (AM) technique often requires a development of process parameters, which generally include four main parameters of laser power (P), scanning speed (v), hatching distance (h), and layer thickness (t). A volume energy density (E), defined by the following Formula (1), is frequently used to compare different parameters:

$$E = P / vht \qquad ( 1 )$$

In this example, five samples are prepared with the laser outputs and scanning speeds varied to determine the appropriate energy density. Table 1 illustrates experimental condition parameters of P1V1, P2V1, P3V1, P1V2, and P1V3 used for preparing the samples. A scanning method includes two border paths and a filling path configured of back-and-forth scans over a maximal length of 10 mm. For each successive slice, the scanning paths are rotated around a laminating direction by an angle of 67° in order to avoid path overlay (refer to FIG. 8(b)).

TABLE 1
Manufacturing Parameters

| | | | | | | Energy |
|---|---|---|---|---|---|---|
| | Parameter | Laser | Scanning | Hatch | | density |
| | name in | power | speed | space | Thickness | E |
| | this study | P (W) | v (mm/s) | h (mm) | t (mm) | (J/mm³) |
| Varying | P1V1 | 200 | 1000 | 0.08 | 0.03 | 104.2 |
| power | P2V1 | 250 | 1000 | 0.08 | 0.03 | 130.2 |
| | P3V1 | 300 | 1000 | 0.08 | 0.03 | 156.3 |
| Varying | P1V2 | 200 | 775 | 0.08 | 0.03 | 134.4 |
| velocity | P1V3 | 200 | 660 | 0.08 | 0.03 | 157.8 |

Two sections of each specimen are cut along the laminating direction. Samples are polished using SiC polishing paper with grit size from 600 to 4000, followed by Al₂O₃ polishing with a final grain diameter of 0.1 μm, and finally cleaned with ethanol. A porosity of the Fe52-Co48 alloy cubes is observed on two sections along the laminating direction using an optical microscope (Zeiss Axio Imager, Carle Zeiss Microscopy). The microstructure of each Fe52-Co48 alloy cube is evaluated using a scanning electron microscope (Zeiss Supra 40, Carl Zeiss Microscopy) and by X-ray diffraction (XRD) measurements (D8 Brucker, Brucker Corporation) using CoKα radiation. An accelerating voltage is 40 kV, and a current is 13 mA.

Furthermore, energy-dispersive X-ray (EDX) spectroscopy is used to evaluate the Fe and Co concentrations in the Fe52-Co48 alloy cubes (EDX, Brucker Corporation). Subsequently, fully dense and honeycomb Fe52-Co48 alloy plates are prepared with dimensions of 70×5×1.6 mm³. A wall thickness and a cell width of the honeycomb plates are respectively controlled to be 250 μm and 2.5 mm. Electron backscatter diffraction (EBSD) is used to observe fine structures of the Fe52-Co48 alloys. A crystal orientation and a crystal grain diameter of the fully dense Fe52-Co48 alloy plates are evaluated using Atex software.

In order to investigate the vibration and impact-energy-harvesting performance of the Fe52-Co48 alloy plates, a power density, which is an output power divided by the volume of an alloy, is measured. FIG. 9 illustrates schematic diagrams of a vibration and impact-energy-harvesting performance test. A vibration generation system is configured of a shaker (ET-132, Labworks Inc., USA), a linear power amplifier (PA-151, Labworks Inc., USA) and a function generator (33250A, Agilent Technologies Inc., USA) to control a waveform and a frequency of output vibration. In the present example, sinusoidal vibration is employed.

Twenty-five mm from the ends of the Fe52-Co48 alloy plates (effective length of 45 mm) are fixed to the shaker and then connected to a data logger to obtain output voltages during vibration between 200 Hz and 600 Hz. For the impact-energy-harvesting test, the ones in which 25 mm from the ends of the fully dense and honeycomb Fe52-Co48 alloy plates (effective length of 45 mm) are vertically fixed to a mold are used. Three specimens are prepared for each structure.

Then, the fully dense and honeycomb Fe52-Co48 alloy plates and an impulse hammer (GK-3100, Ono Sokki Co., Ltd., Japan) are connected to a data logger (NR-500, KEYENCE Corporation, Japan) with a resistance value of 1 MΩ. Accordingly, an impact stress generated by the impulse hammer and the output voltages of the specimens can be recorded by a computer. Usually, in order to obtain a large output voltage and power, it is necessary to rotate a magnetic domain of the Fe52-Co48 alloy plate as much as possible in a coil. Therefore, experiments are conducted so as to apply large compressive stresses to elongated plate-shaped structures. A coil resistance is 11.42 kΩ, a load resistance is 11.72 kΩ, a coil contains 28,000 turns, and a coil diameter is 0.05 mm. Before the vibration and impact-energy-harvesting test, a resonant frequency and an optimal resistance value are first determined required to obtain the maximum output power from the honeycomb-structured Fe52-Co48 alloy plate at high densities.

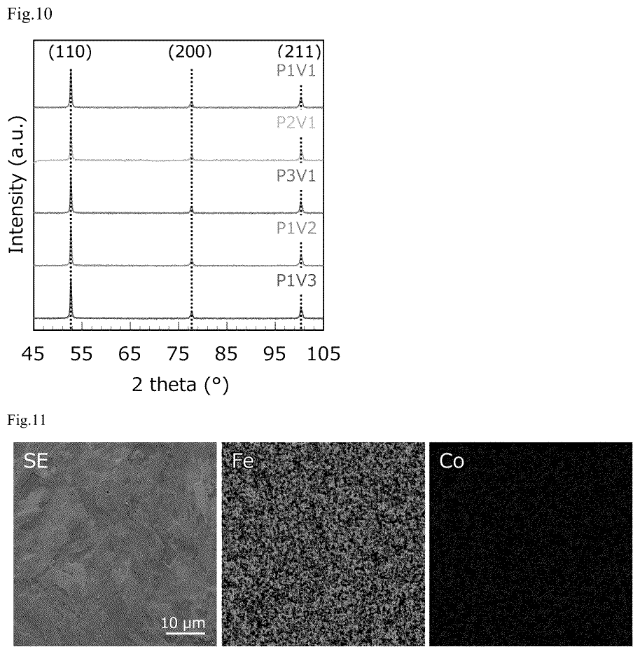

FIG. 10 illustrates XRD patterns of the Fe52-Co48 alloy cubes obtained using each manufacturing parameter. The profile of the alloy obtained using each manufacturing parameter contains three strong diffraction peaks, respectively corresponding to (110), (200), and (211) crystal planes. The profile is configured of three strong diffraction peaks, respectively corresponding to (110), (200) and (211) crystal planes of a body-centered cubic (bcc) phase for each process parameter. A lattice constant is estimated to be 0.2852 nm, which is in close agreement with a value of 0.2855 nm of an arc melted FeCo.

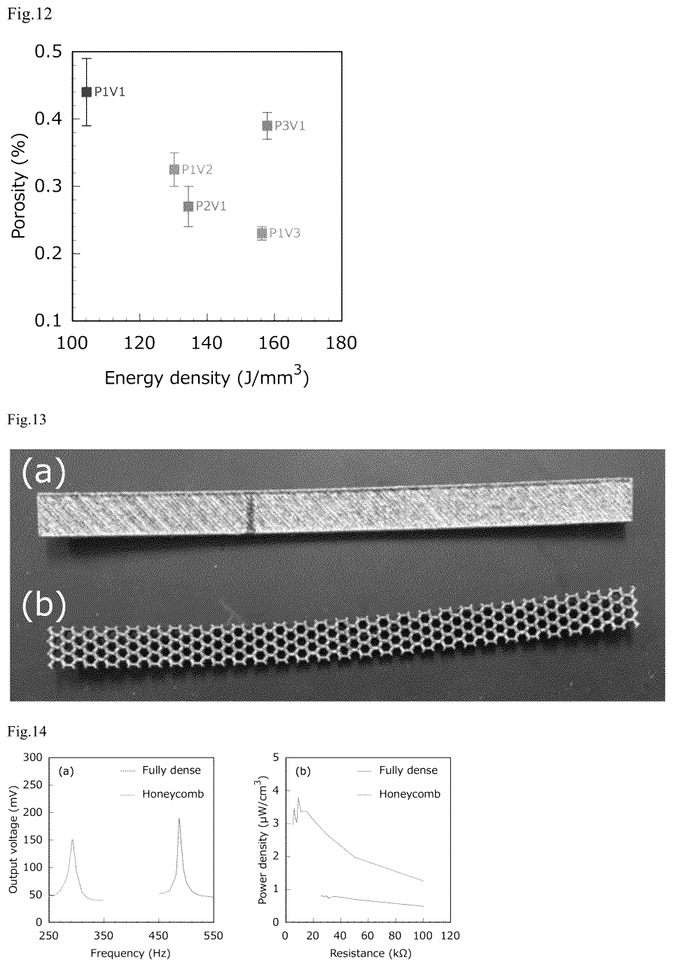

FIG. 11 illustrates a secondary electron image and EDX maps of the Fe52-Co48 alloy cube manufactured using a P2V1 parameter. The fine structure appears to be homogeneous, without precipitation or chemical segregation. FIG. 12 illustrates a relationship between a porosity and an energy density of the Fe52-Co48 alloy cubes manufactured using each parameter. In the Fe52-Co48 alloy cube manufactured using the P2V1 parameters, the porosity is 1.5%. A relative density of each Fe52-Co48 alloy cube exceeded 99.5%, regardless of the manufacturing parameters. The densities of the cubes tended to increase with the volume energy density, except for a case of 300 W of power, where a keyhole region is expected.

FIG. 13 illustrates an outer appearance of an Fe52-Co48 alloy plate manufactured using the P2V1. Plates respectively having a fully dense structure and a honeycomb structure can be manufactured using LPBF.

FIG. 14(a) illustrates a relationship of an output voltage with respect to a frequency of the Fe52-Co48 alloy plate under the vibration-energy-harvesting test. The resonant frequencies of the fully dense and honeycomb-structured Fe52-Co48 alloy plates are respectively 487 Hz and 293 Hz. This result indicates that the structural change of the Fe52-Co48 alloy plate shifts its resonant frequency, with the honeycomb structure having a lower resonant frequency than the fully dense structure. Since vibration frequencies in daily life tend to be low, vibration-energy-harvesting devices preferably have a low resonant frequency.

Moreover, a relationship between the power density and the resistance are investigated at these resonant frequencies (refer to FIG. 14(b)). As illustrated in FIG. 14(b), the honeycomb structure body exhibits a power density 4.7 times larger than that of the fully dense structure under a vibration test. It has been known that the maximum output voltage of a notched FeCo/Ni-clad plate cantilever is higher than the maximum output voltage of a cantilever without a notch. It is considered that this result is attributed to the stress concentration generated by the notch. Accordingly, the remarkable output power density obtained from the honeycomb structure is also likely due to a high-stress level.

Such a honeycomb-structured plate thus seems to work effectively in generating electricity in the light of both the resonant frequency and the power density.

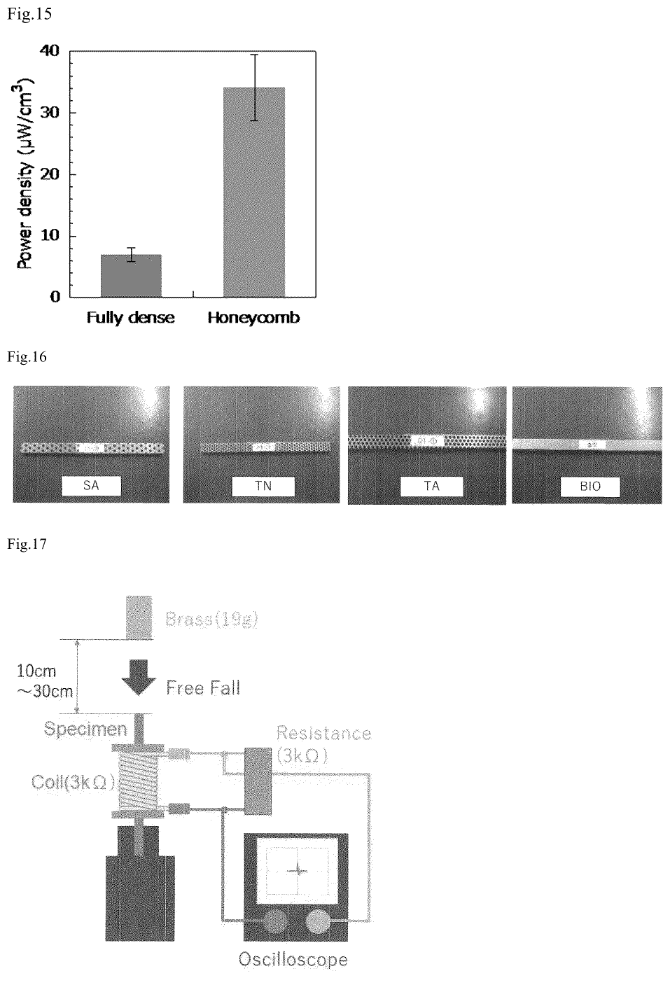

FIG. 15 illustrates power densities of the Fe52-Co48 alloy plate under an impact-energy-harvesting test. As illustrated in FIG. 15, the honeycomb structure body exhibits a power density 4.9 times larger than that of the fully dense structure body under the impact test. During the impact test, the honeycomb-structured plates do not fail.

It has been well known that magnetostrictive materials can be used as particulate matter sensors by utilizing a shift in resonant frequencies or output voltages. A sensitivity of a magnetostrictive particulate matter sensor is dominated by its weight. Accordingly, such a sensor must be lightweight to obtain high sensitivity. The honeycomb and other designed structure bodies can be used to provide both high energy-harvesting performance and high sensitivity as a particulate matter sensor.

As described above, it is found out that, as a result of evaluating the vibration and impact-energy-harvesting performance of the plate materials having a honeycomb structure, the resonant frequency shifts to a lower value with the honeycomb structure. Furthermore, the honeycomb structure bodies exhibit high power densities under the vibration test. In accordance with the honeycomb structure bodies, efficient electric generation can be expected.

### Example 3

In accordance with the method in Example 1, four types of samples are prepared using an alloy based on Fe and 70% by mass of Co having a positive magnetostriction constant. The samples to be used include a plate material (BI0) without a through hole, in which a longitudinal direction and a rolling direction is the same, a honeycomb-shaped plate material (SA) having a small number of through holes in the plate thickness direction, a honeycomb-shaped plate material (TA) having a large number of through holes in the plate thickness direction, and a honeycomb-shaped plate material (TN) made by stacking two plates having a large number of through holes in the plate thickness direction, in which the through holes are shifted from each other by half the hole diameter. FIG. 16 illustrates a shape of each sample.

For these four types of samples, an impact-power-generation test is conducted using an impact-energy-harvesting performance test apparatus illustrated in FIG. 17. As illustrated in FIG. 17, the test apparatus includes a coil bobbin 3 kΩ, a load resistance 3 kΩ, and an oscilloscope. The sample is inserted into an inside of the coil bobbin and fixed vertically to a mold, a 19-g brass weight is applied to the sample in free fall from three levels of height (10 cm, 20 cm, and 30 cm) and current values are recorded on a computer.

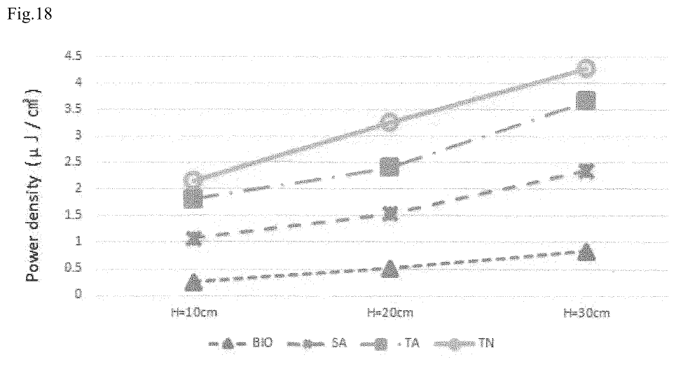

FIG. 18 illustrates the result thereof. FIG. 18 illustrates instantaneous current values (with correction of volume) with respect to heights of free fall of the weight in the impact-power-generation test.

As illustrated in FIG. 18, it proves that the instantaneous current values of the samples (TA) and (TN) having the large number of through holes are larger than those of the sample (BI0) without a through hole and the sample (SA) having the small number of through hole.

What is claimed is:

1. A magnetostrictive material comprising a void.

2. A plate-shaped magnetostrictive material comprising a through hole in a plate thickness direction.

3. An energy converter formed by stacking and coupling a plate-shaped magnetostrictive material including a through hole in a plate thickness direction and a plate material in the plate thickness direction to each other.

4. The energy converter according to claim 3, wherein the plate-shaped magnetostrictive material is formed of a honeycomb structure including a cell constituting the through hole.

5. The energy converter according to claim 4, wherein a cross sectional shape of the cell in the honeycomb structure is polygonal.

6. The energy converter according to any one of claims 3-5, wherein the plate material is made of a magnetostrictive material, a soft magnetic material, or a nonmagnetic material.

7. The energy converter according to any one of claims 3-5, wherein the plate-shaped magnetostrictive material and/or the plate material may be formed of a plurality of pieces, each of which is stacked and coupled in the plate thickness direction.

8. The energy converter according to claim 7, wherein the through hole of the plate-shaped magnetostrictive material is closed at one or both ends by the plate material or another plate-shaped magnetostrictive material.

9. The energy converter according to any one of claims 3-5, wherein the plate-shaped magnetostrictive material is formed of a plurality of pieces, each of which has a different direction of an easy axis of magnetization.

10. The energy converter according to any one of claims 3-5, wherein the plate-shaped magnetostrictive material and the plate material are bonded to each other by diffusion bonding, welding, or an adhesive.

11. The energy converter according to any one of claims 3-5, wherein the energy converter is in an elongated plate shape having a plate thickness that decreases from one end toward the other end.

12. The energy converter according to any one of claims 3-5, wherein the energy converter is in an elongated plate shape having a width that narrows from one end toward the other end.

13. The energy converter according to claim 5, wherein the energy converter is in an elongated plate shape, the cross sectional shape of the cell in the honeycomb structure is a regular hexagon, and a perpendicular line of any side of the cell is inclined at 30 degrees with respect to the overall longitudinal direction.

14. The energy converter according to claim 5, wherein the energy converter is in an elongated plate shape, the cross sectional shape of the cell in the honeycomb structure is a hexagon, the hexagon has two opposing sides that are equal in length, the other four sides are each the same length but longer than the two opposing sides, and perpendicular lines with respect to the two sides are along the overall longitudinal direction.

15. The energy converter according to any one of claims 3-5, wherein the plate-shaped magnetostrictive material is formed of a plurality of pieces, which are stacked and coupled in the plate thickness direction to each other, with the through holes shifted from each other.

16. A manufacturing method of an energy converter, the manufacturing method comprising stacking and coupling a plate-shaped magnetostrictive material including a through hole in a plate thickness direction and a plate material in the plate thickness direction to each other.

17. A vibration power generator comprising a vibration unit formed by supporting the one end of the energy converter according to claim 11 in a cantilever manner, wherein
the vibration power generator is configured to generate electricity by an inverse magnetostriction effect of the plate-shaped magnetostrictive material due to vibration of the vibration unit.

18. A vibration power generator comprising a vibration unit formed by supporting the one end of the energy converter according to claim 12 in a cantilever manner, wherein
the vibration power generator is configured to generate electricity by an inverse magnetostriction effect of the plate-shaped magnetostrictive material due to vibration of the vibration unit.

19. A vibration power generator comprising the energy converter according to any one of claims 3-15, the energy converter being elongated plate shape, one end thereof being supported, wherein
the vibration power generator is configured to generate electricity by an inverse magnetostriction effect of the plate-shaped magnetostrictive material due to an impact in an overall longitudinal direction of the energy converter.
